(19) United States
(12) Patent Application Publication
(10) Pub. No.: US 2006/0188749 A1
(43) Pub. Date: Aug. 24, 2006

(54) Compound film with a nonlinear third order susceptibility, and method for fabricating the same

(75) Inventors: Shinzo Morita, Nagoya City (JP); Shizuyasu Ochiai, Ichinomiya City (JP)

Correspondence Address: OLIFF & BERRIDGE, PLC, P.O. BOX 19928, ALEXANDRIA, VA, 22320, US

(73) Assignee: National University Corporation Nagoya University, Nagoya City (JP)

(21) Appl. No.: 11/387,718

(22) Filed: Mar. 24, 2006

Related U.S. Application Data
(63) Continuation-in-part of application No. 10/367,851, filed on Feb. 19, 2003, now abandoned.

(30) Foreign Application Priority Data
Sep. 12, 2002 (JP) 2002-266,243

(51) Int. Cl. C23C 14/32; B32B 15/04; B32B 9/00

(52) U.S. Cl. 428/698; 204/192.1; 428/457

(57) ABSTRACT

A carbon hydrogen raw material gas and a SF₆ raw material gas are introduced into a chamber with Ar carrier gas, and a high frequency electric power is introduced into the chamber to discharge the raw material gas to be made plasma. At the same time, a metallic plate on a main surface of one of parallel plate electrodes is sputtered to form a compound film made of carbon, sulfide and Au elements which are dispersed in the film matrix made of carbon and sulfide and does not constitute clusters through aggregation.

### CROSS-REFERENCE TO RELATED APPLICATION

This is a continuation-in-part application of application Ser. No. 10/367,851, filed Feb. 19, 2003, incorporated by reference herein in its entirety.

### BACKGROUND

This invention relates to a compound film with a nonlinear third order susceptibly that is preferably usable in optical computing and optical recording technology, and a method for fabricating the same.

The ruby laser was discovered in 1960 by Maiman (see, Maiman, T. H., Nature, 187, 493 (1960)), and then, the nonlinear electro-optic effect of quartz crystal was used for frequency doubling in 1961 (see, Franken, P. A., Hill, A. E., Peters, C. W., Weinreich, G., Phys. Rev. Lett., 7, 118 (1961). The nonlinear electro-optic material research was progressed by the discovery of large nonlinear effect of organic material since 1990. Since the organic material also has a large response velocity, much attention is paid to the organic material in view of the use of optical information processing device in comparison with an inorganic material. As the organic material can be exemplified π-conjugated polymers and organo-metallic compounds.

There are several materials which showed the third-order susceptibility values larger than ˜10⁻⁸ e.s.u. (electrostatic system of merits) for the organic and inorganic compounds. However, they are not useful material because of expensive materials and unstable natures chemically, physically and thermally.

### SUMMARY

It is an object of the present invention to provide a new material with a large nonlinear third order susceptibility.

In order to achieve the above object, this invention relates to a compound film comprising at least carbon, sulfide and Au elements which are dispersed uniformly and does not constitute clusters through aggregation,

wherein said compound film exhibits third order susceptibility.

This invention also relates to a method for fabricating a compound film, comprising the steps of:

preparing a pair of parallel plate electrodes in a chamber,

setting a substrate on a main surface of one of the electrodes which is opposite to the other electrode of the electrodes,

setting an Au plate on a main surface of the other electrode of the electrodes so as to be opposite to the substrate,

introducing, in between the electrodes, at least one of a carbon hydrogen raw material gas and a hydrogen raw material gas, a SF₆ raw material gas and Ar gas to be discharged and made plasma, and

applying a given voltage between the electrodes to sputter the metallic plate under the plasma made of at least one of the carbon hydrogen raw material gas and the hydrogen raw material gas, the SF₆ raw material gas and the Ar gas.

The inventors have studied a compound film including Au or the like. In the studying process, if the compound film includes Au elements at a given ratio, and then, the Au elements are dispersed uniformly due to chemical bond between S—Au and does not constitute clusters in the compound film through aggregation, the compound film can exhibit a large third order susceptibility.

As more Au the compound includes, however, as more clusters Au particles constitute, so that the intended compound film with the large third order susceptibility can not be fabricated. In this point of view, the inventors made an attempt to incorporate Au elements in the compound film at a relatively large ratio not through aggregation. As a result, they found out that if the fabricating method of the present invention as mentioned above is employed, the Au elements can be dispersed uniformly in the compound film even at a relatively large ratio not through aggregation. Accordingly, since the thus obtained compound film, according to the present invention, includes carbon, sulfide, and uniformly dispersed Au elements at the relatively large ratio, the compound film can exhibit a larger third order susceptibility which can be employed in the optical computing and optical recording technology.

In a preferred embodiment of the present invention, the compound film is amorphous. In this case, the compound film can exhibit a larger third order susceptibility.

In another preferred embodiment of the present invention, the carbon elements of the compound film constitute an amorphous carbon matrix and {C—S—Au} molecules are dispersed in the amorphous carbon matrix. In this case, too, the compound film can exhibit a larger third order susceptilibity.

In a further preferred embodiment of the present invention, the content of the Au elements is set to at least 0.1 atomic percentage, more preferably at least 0.5 atomic percentage. In this case, too, the compound film can exhibit a larger third order susceptibility.

In the present invention, for example, employing at least one of the preferred embodiments, the third order susceptibility of the compound film can be 1×10⁻⁸ e.s.u. or over, more preferably 1.7×10⁻⁸ e.s.u. or over.

As mentioned above, according to the present invention can be provided a new material with a large nonlinear third order susceptibility.

### BRIEF DESCRIPTION OF THE DRAWINGS

For better understanding of the present invention, reference is made to the attached drawings, wherein

FIG. 1 is a schematic view showing an apparatus to be employed in the fabricating method of the present invention, and

FIG. 2 is a graph showing the relation between the Au content and the third order susceptibility in a compound film according to the present invention.

### DETAILED DESCRIPTION OF EMBODIMENTS

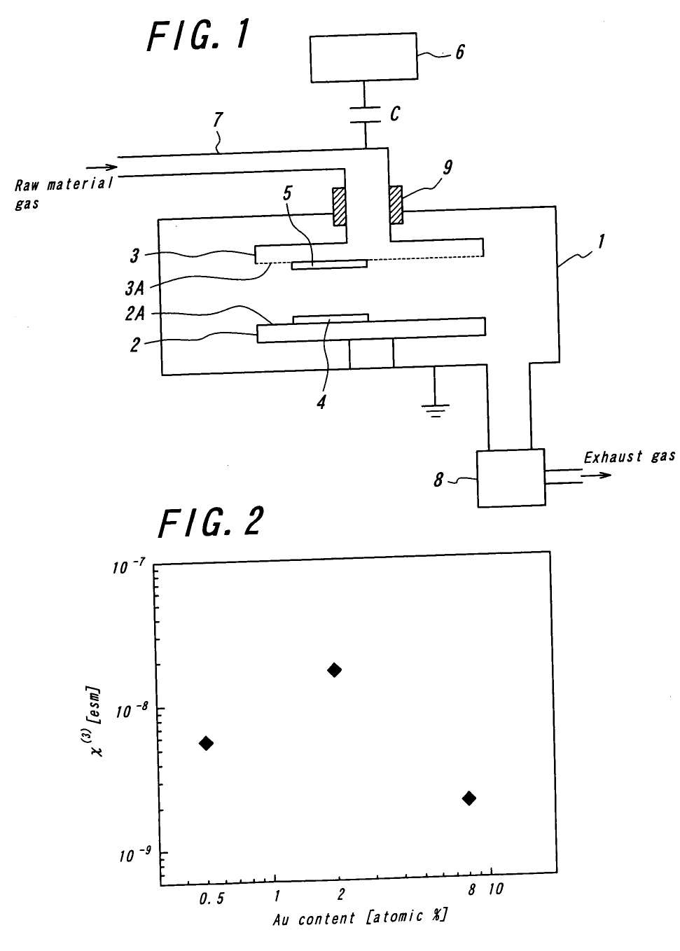

This invention will be described in detail with reference to the accompanying drawings. FIG. 1 is a schematic view showing an apparatus to be employed in the fabricating method of the present invention. In the apparatus illustrated in FIG. 1, a pair of parallel plate electrodes 2 and 3 are disposed so as to be opposite to each other in a chamber 1. A substrate 4 is placed on the main surface 2A of the electrode 2 which is opposite to the electrode 3, and an Au plate 5 is placed on the mesh-like main surface 3A of the electrode 3 which is opposite to the electrode 2.

A gas supply path 7 is so located backward from the electrode 3 as to be held by the chamber 1 via an insulating ring 9. A carbon hydrogen raw material gas and an SF₆ raw material gas are supplied into the chamber 1 from the main surface 3a of the electrode 3 through the gas supply path 7. A high frequency power supply 6 is connected to the chamber 1 via a condenser C. A vacuum pump 8 is provided below the chamber 1 so as to evacuate the remaining carbon hydrogen raw material gas which is not reacted to other raw material gas or the like and then, maintain the pressure inside the chamber 1 uniformly.

As mentioned above, in the apparatus illustrated in FIG. 1, the carbon hydrogen raw material gas and the SF₆ raw material gas are supplied into the chamber 1 via the main surface 3A of the electrode 3 from the gas supply path 7. Then, a high frequency electric power is supplied between the electrodes 2 and 3 from the power supply 6. In this case, the carbon hydrogen raw material gas, the SF₆ raw material gas and Ar gas are discharged to be made plasma. At the same time, since a given voltage is generated between the electrodes 2 and 3 by the self-biasing effect, the Au plate 5 is sputtered.

In the plasma, the carbon hydrogen raw material gas and the SF₆ raw material gas are excited to be decomposed into their respective constituent elements. Therefore, the carbon elements of the carbon hydrogen raw material gas and the sulfide elements of the SF₆ raw material gas are deposited with the sputtered metallic elements of the Au plate 5 on the substrate 4. As a result, a desired compound film can be obtained where the carbon elements, the sulfide elements and the metallic elements are uniformly dispersed.

In the present invention, it is desired that the flow rate ratio of the carbon hydrogen raw material gas and the SF₆ raw material gas is determined stoichiometrically so that the ratio (hydrogen atom/fluorine atom) is set to 1. It is also desired that the pressure inside the chamber 1 is set to 0.2 Torr or below, more preferably set to less than 0.1 Torr. In this case, the desired compound film can be obtained easily.

If the above-mentioned apparatus is employed and at least one of the fabricating conditions is employed, the compound film can be amorphous, preferably such that the carbon elements of the compound film constitute an amorphous carbon matrix and {C—S—Au} molecules are dispersed in the amorphous carbon matrix. In this case, the compound film can exhibit a larger third order susceptilibity.

Also, the content of the Au elements is set to at least 0.1 atomic percentage, preferably at least 0.5 atomic percentage. Therefore, the compound film can exhibit a larger third order susceptibility. For example, the third order susceptibility of the compound film can be 1×10⁻⁸ e.s.u. or over, more preferably 1.7×10⁻⁸ e.s.u. or over.

In this embodiment, although the carbon hydrogen raw material gas and the SF₆ raw material gas are employed, a hydrogen raw material gas may be employed, in addition to or in substitution for the carbon hydrogen raw material gas.

### EXAMPLE

### Example 1

An apparatus as shown in FIG. 1 was employed, and a compound film made of carbon, sulfide and cupper was fabricated as follows. In the apparatus as illustrated in FIG. 1, the pair of electrodes 2 and 3 were made of graphite, and the gap between the electrodes 2 and 3 was set to 1.5 cm. The glass substrate 4 was set on the main surface 2A of the electrode 2, and the Au plate 5 with a size of 50×50 mm² was set on the main surface 3A of the electrode 3. Then, a CH₄ raw material gas, a SH₆ raw material gas and an Ar carrier gas were introduced into the chamber 1. The flow rates of the CH₄ raw material gas, the SF₆ raw material gas and the Ar raw carrier gas were set to 10 sccm, 7 sccm and 15 sccm, respectively. The pressure inside the chamber 1 was set to 0.11 Torr.

Then, a high frequency electric power with an electric power of 100 W and a frequency of 13.56 MHz was introduced into the chamber 1 to discharge the CH₄ raw material gas, the SF₆ raw material gas and the Ar carrier gas and sputter the Au plate 5 for 30 minutes. In this case, the third order susceptibility of the thus obtained compound film was 0.56×10⁻⁸ e.s.u. In this example, the content of Au was 0.5 atomic %.

### Example 2

Except that the flow rates of the CH₄ raw material gas, the SF₆ raw material gas and the Ar raw carrier gas were set to 10 sccm, 10 sccm and 10 sccm, respectively, and the pressure inside the chamber 1 was set to 0.08 Torr, the intended compound film was fabricated in the same manner in Example 1. In this case, the third order susceptibility of the thus obtained compound film was 1.78×10⁻⁸ e.s.u. In this example, the content of Au was 2 atomic %.

### Example 3

Except that the flow rates of the CH₄ raw material gas, the SF₆ raw material gas and the Ar raw carrier gas were set to 9 sccm, 10 sccm and 15 sccm, respectively, and the pressure inside the chamber 1 was set to 0.13 Torr, the intended compound film was fabricated in the same manner in Example 1. In this case, the third order susceptibility of the thus obtained compound film was 0.2×10⁻⁸ e.s.u. In this example, the content of Au was 8 atomic %.

### Comparative Example

Except that the flow rates of the CH₄ raw material gas, the SF₆ raw material gas and the Ar raw carrier gas were set to 15 sccm, 0 sccm and 2 sccm, respectively, and the pressure inside the chamber 1 was set to 0.13 Torr, the intended compound film was fabricated in the same manner in Example 1. In this case, the third order susceptibility of the thus obtained compound film was almost zero e.s.u.

Herein, FIG. 2 is a graph showing the relation between the Au content and the third order susceptibility in the compound films fabricated in the Examples.

Although the present invention was described in detail with reference to the above examples, this invention is not limited to the above disclosure and every kind of variation and modification may be made without departing from the scope of the present invention.

What is claimed is:

1. A compound film comprising at least carbon, sulfide and Au elements which are dispersed uniformly and does not constitute clusters through aggregation,
wherein said compound film exhibits third order susceptibility.

2. The compound film as defined in claim 1, wherein said compound film is amorphous.

3. The compound film as defined in claim 2, wherein said carbon elements constitute an amorphous carbon matrix and {C—S—Au} molecules are dispersed in said amorphous carbon matrix.

4. The compound film as defined in claim 1, wherein the content of said Au elements is set to at least 0.1 atomic percentage.

5. The compound film as defined in claim 4, wherein the content of said Au elements is set to at least 0.5 atomic percentage.

6. The compound film as defined in claim 1, wherein said third order susceptibility is 1×10⁻⁸ e.s.u. or over.

7. The compound film as defined in claim 6, wherein said third order susceptibility is 1.7×10⁻⁸ e.s.u. or over.

8. A method for fabricating a compound film, comprising the steps of:
preparing a pair of parallel plate electrodes in a chamber,
setting a substrate on a main surface of one of said electrodes which is opposite to the other electrode of said electrodes,
setting an Au plate on a main surface of the other electrode of said electrodes so as to be opposite to said substrate,
introducing, in between said electrodes, at least one of a carbon hydrogen raw material gas and a hydrogen raw material gas, a SF₆ raw material gas and Ar gas to be discharged and made plasma, and
applying a given voltage between said electrodes to sputter said metallic plate under said plasma made of said at least one of said carbon hydrogen raw material gas and said hydrogen raw material gas, said SF₆ raw material gas and said Ar gas.

9. The fabricating method as defined in claim 8, wherein the flow rate ratio of said at least one of said carbon hydrogen raw material gas and said hydrogen raw material gas and said SF₆ raw material gas is determined so that the ratio (hydrogen atom/fluorine atom) is set to 1.0.

10. The fabricating method as defined in claim 8, wherein the pressure inside said chamber is set to 0.2 Torr or below.

11. The fabricating method as defined in claim 10, wherein the pressure inside said chamber is set to less than 0.1 Torr.
